(19) United States
(12) Patent Application Publication
(10) Pub. No.: US 2007/0144673 A1
(43) Pub. Date: Jun. 28, 2007

(54) Apparatus for fabricating flat panel display and method for preventing substrate damage using the same

(75) Inventor: Young Min Yeom, Seoul (KR)

Correspondence Address: BIRCH STEWART KOLASCH & BIRCH, PO BOX 747, FALLS CHURCH, VA, 22040-0747, US

(73) Assignee: LG.PHILIPS LCD CO., LTD.

(21) Appl. No.: 11/432,521

(22) Filed: May 12, 2006

(30) Foreign Application Priority Data
Dec. 28, 2005 (KR) 10-2005-0132285

(51) Int. Cl. H01L 21/306; C23F 1/00; C23C 16/00

(52) U.S. Cl. 156/345.54; 118/729; 156/345.24

(57) ABSTRACT

A fabricating apparatus and method for a flat panel display device, are discussed. According to an embodiment, the apparatus includes a chamber including a movable susceptor for supporting the substrate thereon; a first detecting part to detect a descending distance of the susceptor; a robot arm to move the substrate; a second detecting part to detect a separation status of the substrate from the susceptor; and a controller to control a movement of the robot arm in accordance with the detection results of the first and second detecting parts.

This application claims the benefit of the Korean Patent Application No. 10-2005-0132285 filed on Dec. 28, 2005, which is hereby incorporated by reference.

### BACKGROUND OF THE INVENTION

1. Field of the Invention

The present invention relates to a fabricating apparatus for a flat panel display device and a method of preventing substrate damage using the same, and more particularly to a fabricating apparatus of a flat panel display device that is adaptive for preventing a substrate damage phenomenon generated when a robot arm enters a chamber for returning a substrate on which the vacuum deposition is completed, and to a method of preventing the substrate damage using the apparatus.

2. Description of the Related Art

In recent information society, a display device has its importance emphasized more than ever as a visual information communication medium. A cathode ray tube CRT or Braun tube being the current mainstream has a problem in that its weight and size is large.

On the other hand, the flat panel display device includes liquid crystal display LCD, field emission display FED, organic light emitting diode OLED, etc. And,most of them are put to practical use and put on the market.

The liquid crystal display device can be manufactured light, thin, small and short, thereby satisfying the trend of electrical appliances and other devices. And, mass productivity of the liquid crystal device is improved, thereby replacing the cathode ray tubes in many applied fields.

Generally, a liquid crystal display (hereinafter, referred to as “LCD”) device controls the light transmittance of liquid crystal cells which are arranged in a matrix configuration on a liquid crystal display panel by adjusting a video data signal supplied thereto, thereby displaying a picture corresponding to the data signal on the panel.

The liquid crystal display device includes a lower plate where there are formed electrodes for applying electric field to a liquid crystal layer, a thin film transistor for switching the supply of data for each liquid crystal cell, a signal line for supplying the data supplied from the outside to the liquid crystal cells and a signal line for supplying a control signal of the thin film transistor; an upper plate where a color filter, a black matrix, etc. are formed; a spacer formed between the upper plate and the lower plate to secure a fixed cell gap; and a liquid crystal filled in the space provided between the upper and lower plates by the spacer.

In a fabricating method of a flat panel display device inclusive of the liquid crystal display device, an active layer included in a channel part of the thin film transistor and a passivation film protecting the thin film transistor are formed mainly by use of PECVD (plasma enhanced chemical vapor deposition) process. The PECVD process, as shown in FIG. 1, is performed by a fabricating apparatus of the liquid crystal display device, as shown in FIG. 1, according to a related art.

The fabricating device of the flat panel display device shown in FIG. 1 includes a process chamber 2 where a deposition process is performed; and a susceptor 10 which applies heat to a substrate 4 within the process chamber 2 and is used as a lower electrode for generating plasma. A lift pin 6 is installed on the susceptor 10 for supporting the substrate 4. The substrate 4 is transferred onto the susceptor 4 by the robot arm (not shown) and returned after the deposition process. The susceptor 10 is fixed to a supporting stand 20, whereby the susceptor 10 can be positioned at a designated height within the process chamber 2. The susceptor 10 can be moved in a vertical direction by a time belt (not shown) connected to the supporting stand 20.

The time belt is driven by a motor (not shown) to move the supporting stand 20 to a desired height, thereby making the susceptor 10 move to a corresponding position for each process.

The fabricating apparatus of the flat panel display device with such a configuration makes the susceptor 10 in which the substrate 4 is loaded, rise to a position where the deposition process can be progressed, and makes a required film deposited by gas and plasma by applying heat and voltage to the substrate 4.

In the deposition process as described above, a high charge is electrified between the substrate 4 and the susceptor 10 by an RF (radio frequency) discharge, and the charge (static electricity) electrified in this way becomes a cause for making the substrate 4 strongly stick to the susceptor 10. In order to prevent the substrate 4 from sticking to the susceptor 10 when that is undesired, a separate electricity controlling process is generally performed after completing the deposition process. Specifically, the electricity controlling process interposes inert gas such as He, Ne or N2 gas through a gas injection hole of the chamber 2, and makes the interposed non reactive gas into a plasma state by applying an RF power of about 400W, in an attempt to neutralize the charges electrified in the middle part of the substrate 4.

However, it is in fact difficult to completely control electricity because the amount of the static electricity between the substrate 4 and the susceptor 10 occasionally changes due to various factors such as an environmental change within the chamber 2.

Accordingly, in a state that the electricity is not controlled properly, if the susceptor 10 is made to descend in the chamber 2 (e.g., after the deposition process is completed), there is generated a problem that the substrate 4 is not properly separated from the susceptor 10 due to the charge electrified between the substrate 4 and the susceptor 10. This causes damage to the substrate 4 and the susceptor 10.

FIGS. 2 and 3 are cross-sectional diagrams illustrating examples of how the substrate 4 is not properly separated from the susceptor 10 when the susceptor 10 descends in the chamber 2 after the deposition process is completed.

Firstly, as shown in FIG. 2, as the susceptor 10 descends in the chamber 2, a defect is generated due to the electrified charge in the middle part of the substrate 4 where no lift pin 6 exists. Here the defect is that the substrate 4 is not properly separated from the susceptor 10, especially in the middle part. As a result, the substrate 4 becomes bent.

Furthermore, in the state of FIG. 2, even if the adhered middle part of the substrate 4 is later separated from the susceptor 10, the substrate 4 generally flips upwardly and violently shakes due to the abrupt separation from the susceptor 10.

In such a case, the flipped or shaken substrate 4 often does not return to the proper place, and escapes from the lift pin(s) 6, for example, as shown in FIG. 3.

As described above, in a case that the middle part of the substrate 4 is not separated from the susceptor 10 and/or in a case that the substrate 4 escapes from the lift pin(s) 6, there is generated a problem that the substrate 4 and/or the susceptor 10 can be damaged due to the improper separation from each other. Also, a robot arm 30 for returning the substrate 4 is unable to load and/or move the substrate 4 properly and causes damage to the substrate 4 and the robot arm 30 due to the improper positioning of the substrate 4 and its interference with the robot arm 30.

### SUMMARY OF THE INVENTION

Accordingly, it is an object of the present invention to provide a fabricating apparatus of a flat panel display device that is adaptive for preventing a substrate damage phenomenon generated, e.g., when a robot arm enters or move in a chamber for returning a substrate on which a vacuum deposition is completed, and to provide a method of preventing the substrate damage using the fabricating apparatus.

It is another object of the present invention to provide an apparatus and method for preventing substrate damage, which addresses the limitations and disadvantages associated with the related art.

According to an aspect, the present invention provides a fabricating apparatus for a flat panel display device, the apparatus comprising: a chamber where a vacuum deposition is performed; at least one lift pin to support a substrate within the chamber; a susceptor through which the at least one lift pin passes and configured to ascend and descend; a descending distance sensing part to detect a descending distance of the susceptor; a robot arm to move the substrate; a detecting part driven in accordance with the detection of the descending distance sensing part and configured to determine whether or not the substrate stuck to the susceptor is separated from the susceptor; and a controller to control a movement of the robot arm in accordance with the determination of the detecting part.

According to another aspect, the present invention provides a method for preventing a substrate damage upon an entry of a robot arm in a fabricating apparatus for a flat panel display device, the fabricating apparatus including a chamber, a plurality of lift pins for supporting a substrate within the chamber, a susceptor through which the lift pins pass and which is driven to be able to ascend and descend, and a robot arm for returning the substrate, the method comprising: sensing whether or not the susceptor completes the descent of the susceptor; detecting whether or not the substrate stuck to the susceptor by static electricity is separated from the susceptor after completion of the descent of the susceptor; and controlling a movement of the robot arm in accordance with the detection result.

According to another aspect, the present invention provides an apparatus for performing a process on a substrate for a display device, the apparatus comprising: a chamber including a movable susceptor for supporting the substrate thereon; a first detecting part to detect a descending distance of the susceptor; a robot arm to move the substrate; a second detecting part to detect a separation status of the substrate from the susceptor; and a controller to control a movement of the robot arm in accordance with the detection results of the first and second detecting parts.

According to another aspect, the present invention provides a method for performing a process on a substrate for a display device, using an apparatus, the apparatus including a chamber having a movable susceptor for supporting the substrate thereon, and a robot arm to move the substrate, the method comprising: detecting a descending distance of the susceptor; detecting a separation status of the substrate from the susceptor; and controlling a movement of the robot arm in accordance with the detection results of the detecting steps.

These and other objects of the present application will become more readily apparent from the detailed description given herein after. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

These and other objects of the invention will be apparent from the following detailed description of the embodiments of the present invention with reference to the accompanying drawings, in which:

FIG. 1 is a cross-sectional view of a fabricating apparatus of a flat panel display device used in a vacuum deposition process of the related art;

FIGS. 2 and 3 are cross-sectional views illustrating examples of a substrate that is not properly separated from a susceptor according to the related art when the susceptor descends in the chamber after a deposition process is completed;

FIG. 4 is a cross-sectional view of a fabricating apparatus of (or for) a flat panel display device according to an embodiment of the present invention;

FIG. 5 is a block diagram of a controlling apparatus which can be used in or with the fabricating apparatus of FIG. 4 according to an embodiment of the present invention; and

FIG. 6 is a flow chart of a method of preventing damage to a substrate of a display device according to an embodiment of the present invention.

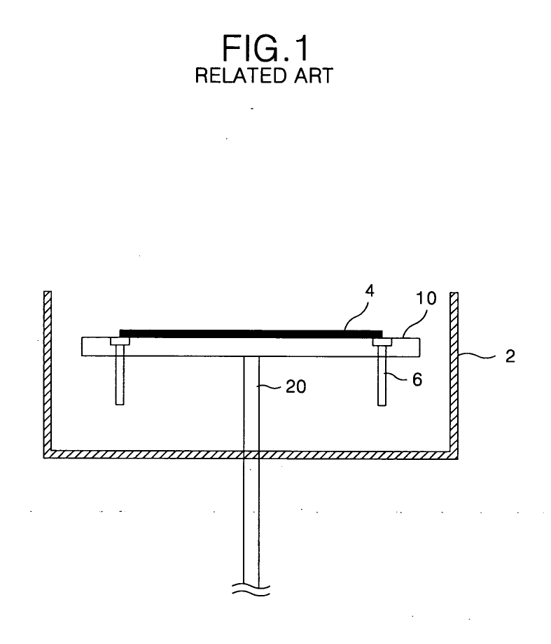

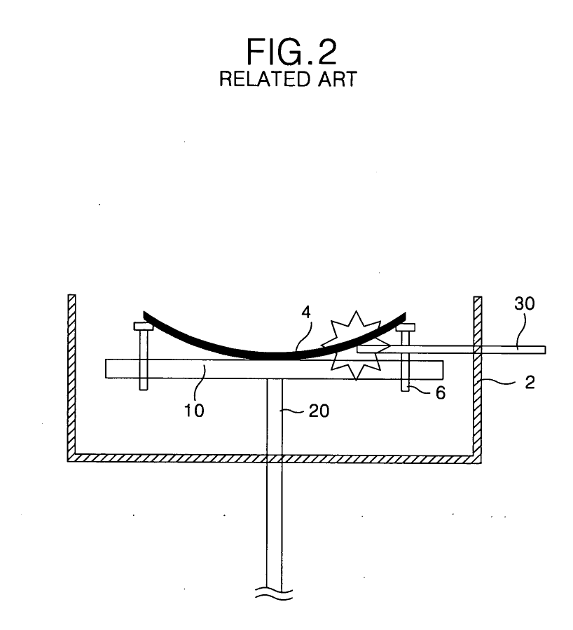

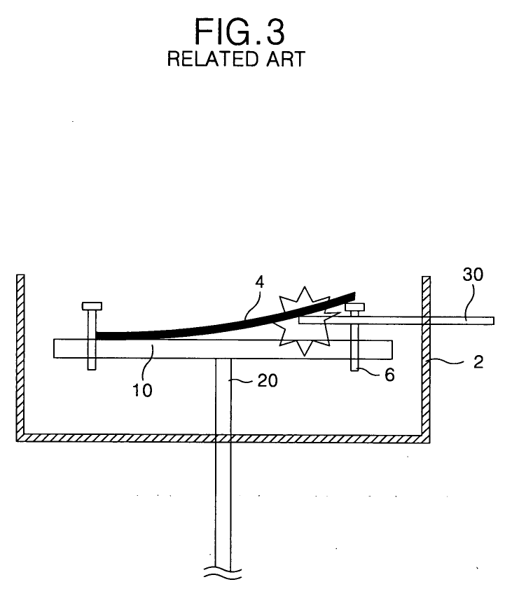

### DETAILED DESCRIPTION OF THE PREFERRED EMBODIMENTS

Reference will now be made in detail to the preferred embodiments of the present invention, examples of which are illustrated in the accompanying drawings.

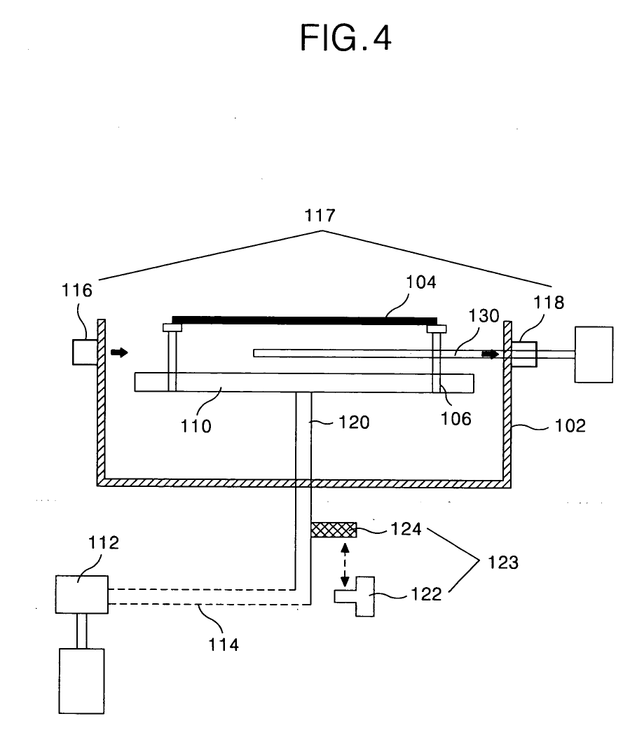

With reference to FIGS. 4 to 6, embodiments of the present invention will be explained as follows.

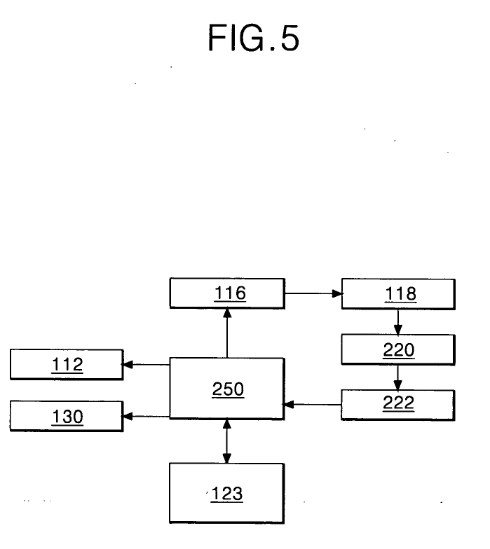

FIG. 4 is a cross-sectional diagram of a fabricating apparatus for forming a substrate of a flat panel display device or other device according to an embodiment of the present invention, and FIG. 5 is a block diagram of a controlling apparatus usable in or with the fabricating apparatus, which prevents or minimizes damage to the substrate that can be caused by a robot arm entry or movement in the fabricating apparatus according to an embodiment of the present invention. The controlling apparatus (e.g., the controller 250) of FIG. 5 controls the fabricating apparatus of FIG. 4. Also the controlling apparatus of FIG. 5 can be part of the fabricating apparatus of FIG. 4 or can be a separator device from the fabricating apparatus of FIG. 4.

Referring to FIGS. 4 and 5, the fabricating apparatus for a flat panel display device according to the present invention includes a process chamber 102 where a deposition process is performed; one or more lift pins 106 for supporting a substrate 104 within the process chamber 102; a susceptor 110 through which the lift pins 106 go and which is driven to be able to ascend and descend; a descending distance sensing part 123 for sensing a descending distance of the susceptor 110; a robot arm 130 for returning the substrate 104 after completing the descent of the susceptor 110; a detecting part 117 for detecting whether or not the substrate 104 stuck to the susceptor 110 is separated from the susceptor 110 by static electricity after completing the descent of the susceptor 110; and a controller 250 (in the controlling apparatus) for controlling whether or not the robot arm 130 enters the chamber 102 (or whether or not the robot arm 130 is moved closer to the substrate 104) in accordance with the information detected by the detecting part 117. All the components of the fabricating apparatus and the controlling apparatus are operatively coupled.

The descending distance sensing part 123 includes a sensed body 124 installed in or on one side of a supporting stand 120 of the susceptor 110; and a descending distance sensor 122 which irradiate light to the sensed body 124 that descends together with the supporting stand 120 upon the descent of the susceptor 110 so as to sense the descending distance of the susceptor 110.

The detecting part 117 includes a light emitting sensor 116 for irradiating light to a spacer formed between the substrate 104 and the susceptor 110 in order to detect whether the substrate 104 stuck to the susceptor 110 is separated from the susceptor 110 by static electricity after completing the descent of the susceptor 110; and a light receiving sensor 118 for receiving the irradiated light. For instance, depending on the presence/absence or the level of the light detected by the light receiving sensor 118, the light receving sensor 118 (or the controller 250) can determine if the substrate 104 is completely separated from the susceptor 110.

An operating process of the fabricating apparatus of the flat panel display device with such a configuration according to an embodiment of the present invention will be described as follows.

In order to process or pattern the substrate 104 upon which the deposition has been completed, the susceptor 110 descends in the chamber 102 as far as a designated distance.

At this moment, because the susceptor 110 is fixed to the supporting stand 120, the susceptor 110 is made to move downwardly in a vertical direction by, e.g., a time belt 114 connected to the supporting stand 120 and a motor 112 for driving the time belt 114.

In this way, the descending distance sensor 122 for sensing the descending distance of the susceptor 110 starts to sense at the moment that the susceptor 110 fixed to the standing stand 120 descends along with the supporting stand 120 by the operation of the time belt 114 driven by the motor 112.

Herein, the descending distance sensor 122 as an example can be composed of the light emitting and receiving parts integrated into one module, and receives a reflected light through the light receiving part if the light generated from the light emitting part is reflected from the sensed body 124 installed in one side of the supporting stand 120. And, the descending distance sensor 122 can convert the received light into an electric signal, and can sense the descending distance of the susceptor 110 on the basis of the current amount of the electric signal.

The descending distance sensor 122 transmits the determined descending distance sensing value to the controller 250 continuously from the starting point of time of the descent of the susceptor 110. Thus the controller 250 is made to judge the ending point of the time of the descent of the susceptor 110. For instance, if the descending distance sensing value satisfies a designated reference value, i.e., if the susceptor sufficiently descends to form a space into which the robot arm 130 can enter or can be placed (under the substrate 104) for moving it, the drive of the motor 112 is stopped by the controller 250, whereby the descent of the susceptor 110 is stopped or completed.

On the other hand, a high charge is electrified between the substrate 104 and the susceptor 110 by an RF discharge for a deposition process, and this may generate a phenomenon that the substrate 104 is not properly separated from the susceptor 110 by static electricity during the descent or even after the descent of the susceptor is completed. Because of this, an electricity controlling treatment is performed in order to neutralize the charge electrified, before the susceptor 110 is made to descend, but it is in fact difficult to perfectly control electricity due to various factors such as environmental change, etc. within the chamber 102.

Accordingly, if the descent of the susceptor 120 is completed, the present invention controls the entry of the robot arm 130 by detecting whether or not the substrate 104 is properly separated from the susceptor 110 before the robot arm 130 can enter the chamber 102. As a variation, if the descent of the susceptor 120 is completed, the present invention can control when the robot arm is placed at or closer to the substrate to move the substrate according to whether or not the substrate 104 is properly separated from the susceptor 110. As a result, damage to the substrate, which may be caused by the robot arm, can be prevented.

To this end, the moment the susceptor 110 fixed to the supporting stand 120 moves as far as a designated distance along with the supporting stand 120 by the operation of the time belt 114 caused by the drive of the motor 112 to complete the descent, the light emitting sensor 116 installed near one side of the susceptor 110 transmits light towards a space formed between the substrate 104 and the susceptor 110. The transmitted light would impinge on the light receiving sensor 118 installed near the other side of the susceptor 110, if the substrate 104 is completely separated from the susceptor 110. Thus the controller 250 can determine whether or not the substrate 104 is completely separated from the susceptor 110 by examining the light detection result from the light receiving sensor 118.

Herein, the light supplied to or impinging on the light receiving sensor 118 is converted into an electrical signal through a photo electric converter 220 to be inputted to an A/D converter 222. The analog signal inputted through the A/D converter 222 is converted into a digital signal value to be inputted to the controller 250, and the inputted light amount value is compared with a pre-set reference light amount value by the controller 250 to judge whether or not the substrate 104 is completely separated from the susceptor 110.

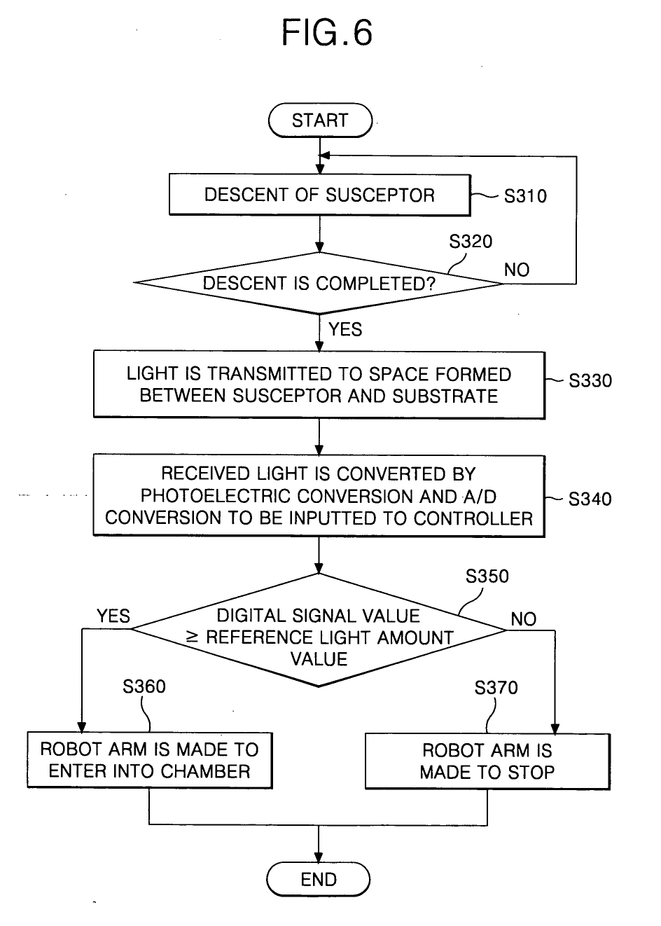

The controller 250 then controls whether or not the robot arm 130 is made to enter into the chamber 102 in accordance with this judgment result, which will be described in more detail by referring to FIG. 6.

FIG. 6 is a flow chart of a method that can prevent damage to a substrate caused by a robot arm entry or movement in the chamber in the fabricating apparatus according to an embodiment of the present invention. This method can be implemented by the apparatuses of FIGS. 4 and 5, but can equally be implemented in other suitable device/system.

Referring to FIG. 6, firstly, the susceptor (e.g., 110 in FIG. 4) descends as far as a designated distance for providing an entry space of the robot arm (e.g., 130 in FIG. 4) so that the substrate upon which the deposition process has been completed can be transferred or moved to a next process location. (S310)

At this moment, the descending distance sensor located on one side of the susceptor transmits a descending distance sensing value to the controller 250 continuously from the starting point of time of the descent of the susceptor, and the controller 250 judges whether or not the susceptor is made to descend continuously by comparing the transmitted descending distance sensing value with the designated reference value.

If the sensing value (e.g., from the sensor 122) satisfies the designated reference value, i.e., if the susceptor sufficiently descends to form a space into which the robot arm 130 can enter, the controller 250 stops the drive of the motor which makes the susceptor descend, thereby stopping the descent of the susceptor. On the contrary, if the sensing value does not satisfy the designated reference value, the controller 250 makes the susceptor descend until the sensing value satisfies the designated reference value by maintaining or controlling the drive of the motor. (S320)

In this way, if the descent of the susceptor is completed, the controller 250 should then receive detection information about whether or not the substrate is properly separated from the susceptor before the robot arm is made to enter into the chamber (or before the robot arm is made to move closer to the substrate).

To this end, the moment the susceptor fixed to the supporting stand descends as far as the designated distance along with the supporting stand by the operation of the time belt caused by the drive of the motor (or by other means) to complete the descent, the light emitting sensor (e.g., 116) installed near one side of the susceptor transmits light towards any space formed between the substrate and the susceptor in accordance with the control of the controller 250. (S330)

The light receiving sensor (e.g., 118) installed near the other side of the susceptor receives the transmitted light or portion thereof according to the separated space between the substrate and the susceptor. The light detected by the light receiving sensor is converted into an electrical signal through the photoelectric converter (e.g., 220) to be inputted to the A/D converter (e.g., 222), and the analog signal inputted through the A/D converter is converted into the digital signal value to be inputted to the controller 250. (S340)

Herein, in case that the substrate is not properly separated from the susceptor (e.g., in case that the middle part of the substrate is not separated from the susceptor or the substrate escapes from the lift pin), the transmitted light from the light emitting sensor 116 is reflected by the substrate or interfered. Thus the amount of the light transmitted to or detected by the light receiving sensor 118 is reduced in comparison with the amount of the emitted light. By comparing these two amounts, the controller 250 can determine the separation status of the substrate with respect to the susceptor.

The controller 250 compares the inputted digital signal value with the pre-set reference light amount value (a digital signal value corresponding to the amount of the emitted light) by use of such a point, thereby judging whether or not the substrate is completely separated from the susceptor. (S350)

As a result of the above comparison at step S350, if the inputted digital signal value is higher than (or equal to) the pre-set reference light amount value, the controller 250 judges that the substrate is completely separated from the susceptor and controls the robot arm, such that the robot arm is made to enter into the chamber (or made to move closer to the substrate) for moving the substrate. (S360)

On the contrary, as a result of the above comparison at step S350, if the inputted digital signal value is less than the pre-set reference light amount value, the controller 250 judges that the substrate is not completely separated from the susceptor, and thus the robot arm is prohibited to enter into the chamber (or to move closer to the substrate). (S360)

In the above example, although the substrate separation status detection result is used to determine whether to have the robot arm enter or not enter into the chamber, the same detection result can be used to control any movement of the robot arm according to the present invention. For instance, the same detection result can be used to control when to move the robot arm already in the chamber to move closer to (or below) the substrate to move the substrate within or out of the chamber.

Accordingly, the movement of the robot arm towards the substrate is controlled according to the separation status of the substrate in the present invention. In case that the middle part of the substrate is not separated from the susceptor or the substrate escapes from the lift pin, a problem of damaging the substrate by the robot arm is effectively addressed by the present invention.

The flat panel display device according to the present invention can be, but is not limited to, a liquid crystal display LCD, a field emission display FED, an organic light emitting diode OLED, etc. However, the present invention is not limited to flat panel display devices, but is applicable wherever a separation problem exists between a substrate and a susceptor, and a robot arm (or the like) movement is needed to moved the substrate (or the like). The substrate placed on the susceptor in the present invention can be a substrate of a flat panel display device or other display devices or other suitable devices. The substrate can be, e.g., a glass substrate.

As described above, the fabricating apparatus including the controlling apparatus for the flat panel display device and a method for preventing the damage of the substrate using the same according to the present invention, detect whether or not the substrate is separated from the susceptor by use of a separate optical sensor and control the entry of the robot arm into the chamber (or movement thereof) on the basis of this detection, thereby preventing the substrate damage by the operation of the robot arm within the chamber.

Although the present invention has been explained by the embodiments shown in the drawings described above, it should be understood to the ordinary skilled person in the art that the invention is not limited to the embodiments, but rather that various changes or modifications thereof are possible without departing from the spirit of the invention. Accordingly, the scope of the invention shall be determined only by the appended claims and their equivalents.

What is claimed is:

1. A fabricating apparatus for a flat panel display device, the apparatus comprising:
a chamber where a vacuum deposition is performed;
at least one lift pin to support a substrate within the chamber;
a susceptor through which the at least one lift pin passes and configured to ascend and descend;
a descending distance sensing part to detect a descending distance of the susceptor;
a robot arm to move the substrate;
a detecting part driven in accordance with the detection of the descending distance sensing part and configured to determine whether or not the substrate stuck to the susceptor is separated from the susceptor; and
a controller to control a movement of the robot arm in accordance with the determination of the detecting part.

2. The fabricating apparatus according to claim 1, wherein the detecting part includes:
a light emitting part to transmit light towards a space formed between the susceptor and the substrate; and
a light receiving part to receive the transmitted light.

3. The fabricating apparatus according to claim 2, wherein the light emitting part irradiates light after completing the descent of the susceptor in accordance with control of the controller.

4. The fabricating apparatus according to claim 3, wherein the controller prohibits an entry of the robot arm into the chamber if an amount of a detected light transmitted from the light receiving part is less than a designated reference light amount, and the controller allows the entry of the robot arm into the chamber if the amount of the detected light transmitted from the light receiving part is not less than the designated reference light amount.

5. The fabricating apparatus according to claim 1, wherein the detecting part begins to determine whether or not the substrate stuck to the susceptor is separated from the susceptor, after the vacuum deposition is completed and the susceptor has descended to a certain level.

6. A method for preventing a substrate damage upon an entry of a robot arm in a fabricating apparatus for a flat panel display device, the fabricating apparatus including a chamber, a plurality of lift pins for supporting a substrate within the chamber, a susceptor through which the lift pins pass and which is driven to be able to ascend and descend, and a robot arm for returning the substrate, the method comprising:
sensing whether or not the susceptor completes the descent of the susceptor;
detecting whether or not the substrate stuck to the susceptor by static electricity is separated from the susceptor after completion of the descent of the susceptor; and
controlling a movement of the robot arm in accordance with the detection result.

7. The method according to claim 6, wherein the detecting step includes:
transmitting light to a space formed between the susceptor and the substrate after completion of the descent of the susceptor; and
detecting the transmitted light.

8. The method according to clam 7, wherein the controlling step prohibits an entry of the robot arm into the chamber if the amount of the detected light is less than a designated reference light amount, and allows the entry of the robot arm into the chamber if the amount of the detected light is not less than the designated reference light amount.

9. An apparatus for performing a process on a substrate for a display device, the apparatus comprising:
a chamber including a movable susceptor for supporting the substrate thereon;
a first detecting part to detect a descending distance of the susceptor;
a robot arm to move the substrate;
a second detecting part to detect a separation status of the substrate from the susceptor; and
a controller to control a movement of the robot arm in accordance with the detection results of the first and second detecting parts.

10. The apparatus according to claim 9, wherein the second detecting part begins detecting the separation status of the substrate from the susceptor, after the first detecting part detects that the susceptor has descended a predetermined distance.

11. The apparatus according to claim 10, wherein the susceptor begins to descend, after the process on the substrate has been completed.

12. The apparatus according to claim 11, wherein the controller moves the robot arm, once the controller determines that the substrate is completely separated from the susceptor.

13. The apparatus according to claim 12, wherein the controller permits entry of the robot arm into the chamber, if the controller determines that the substrate is completely separated from the susceptor.

14. The apparatus according to claim 12, wherein the controller prohibits entry of the robot arm into the chamber, if the controller determines that the substrate is not completely separated from the susceptor.

15. The apparatus according to claim 9, wherein the second detecting part includes:
a light emitting unit to generate and transmit light towards a space formed between the susceptor and the substrate; and
a light receiving unit to receive and detect any light transmitted through the space from the light emitting unit.

16. The apparatus according to claim 9, wherein the display device is a flat panel display device.

17. A method for performing a process on a substrate for a display device, using an apparatus, the apparatus including a chamber having a movable susceptor for supporting the substrate thereon, and a robot arm to move the substrate, the method comprising:
detecting a descending distance of the susceptor;
detecting a separation status of the substrate from the susceptor; and
controlling a movement of the robot arm in accordance with the detection results of the detecting steps.

18. The method according to claim 17, wherein the step of detecting the separation status of the substrate from the susceptor starts, after the susceptor has descended a predetermined distance.

19. The method according to claim 18, wherein the susceptor begins to descend, after the process on the substrate has been completed.

20. The method according to claim 17, wherein the controlling step moves the robot arm, once the detecting step detects that the substrate is completely separated from the susceptor.

21. The method according to claim 20, wherein the controlling step permits entry of the robot arm into the chamber, if the detecting step detects that the substrate is completely separated from the susceptor.

22. The method according to claim 20, wherein the controlling step prohibits entry of the robot arm into the chamber, if the detecting step detects that the substrate is not completely separated from the susceptor.

23. The method according to claim 17, wherein the step of detecting the separation status includes:
transmitting, from one side of the susceptor, light towards a space formed between the susceptor and the substrate; and
detecting, from another side of the susceptor, any light transmitted through the space from the one side of the susceptor.
